(19) United States
(12) Patent Application Publication
(10) Pub. No.: US 2025/0326050 A1
(43) Pub. Date: Oct. 23, 2025

(54) INTEGRATED CIRCUIT LASER MARKING SYSTEM

(71) Applicant: Texas Instruments Incorporated, Dallas, TX (US)

(72) Inventors: BO LIN, Chengdu (CN); CHENGGONG ZHENG, Chengdu (CN)

(21) Appl. No.: 18/731,206

(22) Filed: May 31, 2024

Related U.S. Application Data
(63) Continuation of application No. PCT/CN2024/089399, filed on Apr. 23, 2024.

(51) Int. Cl. B23K 26/0622; B23K 101/40; H01L 21/78; H01L 23/544

(52) U.S. Cl. CPC B23K 26/0624; H01L 21/78; H01L 23/544; B23K 2101/40; H01L 2223/54406

(57) ABSTRACT

A method forms an integrated circuit by forming circuitry relative to a first side of a semiconductor layer and an alphanumeric character having a plurality of linear segments on a surface comprising, or fixed relative to, a second side of the semiconductor layer opposite the first side. The forming of an alphanumeric character comprises controlling a tip of a laser to point to a series of laser pulse target positions along a path of the surface while enabling the laser to selectively apply light pulses to form a surface depression corresponding to each light pulse and along at least a portion of the path, the path traversing from a first linear segment of the plurality of linear segments to a final linear segment of the plurality of linear segments, without any segment of the plurality of segments having a start point overlapping a start point of a previously-formed segment.

### CROSS-REFERENCE TO RELATED APPLICATION

Not applicable.

### TECHNICAL AREA

Described examples relate to semiconductor device fabrication, and more particularly, but not exclusively, to laser marking a semiconductor wafer.

### BACKGROUND

Numerous integrated circuits (ICs) are typically formed from a semiconductor wafer, after which the ICs are separated from one another and the wafer. Packaging with respect to each IC may occur at different times. In one packaging example, the ICs are each first separated from the wafer, sometimes referred to as singulation. Thereafter, each separated IC is attached to a substrate, such as a leadframe or laminate, connections are made, and then the entire structure is encapsulated with conductors extending from the interior to the exterior of the package. In another packaging example, sometimes referred to as wafer level chip scale packaging (WLCSP), an entire wafer of ICs is packaged in common steps, without a separate substrate per singulated IC. Instead, WLCSP typically involves various packaging-related steps while all ICs remain together as part of the wafer. For example, WLCSP forms a repassivation layer across the entire wafer and therefore applying to all of its ICs. As another example, WLCSP couples respective conductors (e.g., conductive bumps) to each IC at a same time. Particularly, each IC includes one or more bond pads, and the previously-formed repassivation layer, so the conductor step places one or more conductive bumps to respective bond pad(s), for each IC. The conductive bumps are connected either directly, or through an intermediate conductive layer, along a first side of the wafer to the bond pads.

On a second side of the wafer, sometimes referred to as the wafer backside, the backside may remain exposed or may include a liquid or film layer, and character (e.g., laser) marking may be performed on either the backside or a layer on it. In this process, a laser is controlled with certain parameters to selectively trace the laser light along a surface. For example, in WLCSP, typically laser marking is used on the wafer backside (or a backside layer) and for each IC, that is, on the side opposite that to which electrical connection(s) is made. The laser trace includes laser pulses, each of which creates a corresponding surface depression, so that collectively a sequence of depressions provides a permanent indication, which may present a pattern and/or one or more alphanumeric (or other) characters. These indications can be used to identify part numbers, device attributes, and the like. Laser marking may provide certain benefits, for example including any one or more of marking without protective assembly materials, high precision, non-physical contact, environmental friendliness, and still others.

While the preceding may have implementation in various baseline devices, this document provides examples that may improve on certain of the above concepts, as detailed below.

### SUMMARY

In an example, a method of forming an integrated circuit is described. The method forms circuitry relative to a first side of a semiconductor layer, and it forms an alphanumeric character having a plurality of linear segments on a surface comprising, or fixed relative to, a second side of the semiconductor layer opposite the first side. Each linear segment in the plurality of linear segments has a start point and an end point. The forming of an alphanumeric character comprises controlling a tip of a laser to point to a series of laser pulse target positions along a path of the surface while enabling the laser to selectively apply light pulses to form a surface depression corresponding to each light pulse and along at least a portion of the path, the path traversing from a first linear segment of the plurality of linear segments to a final linear segment of the plurality of linear segments, without any segment of the plurality of segments having a start point overlapping a start point of a previously-formed segment.

Other aspects are also described and claimed.

### BRIEF DESCRIPTION OF THE DRAWINGS

FIG. 1 is a block diagram of a laser marking system and corresponding IC wafer.

FIG. 2 is a plan view of the backside of the FIG. 1 IC wafer.

FIG. 3A illustrates a laser SCANNER PATH for example along a line, and related timing events.

FIG. 3B illustrates laser control signals corresponding to certain FIG. 3A timing events.

FIG. 4A illustrates a first example of a laser SCANNER PATH, forming an alphanumeric character (e.g., the letter ‘Q’) using the FIG. 1 system.

FIG. 4B illustrates laser control signals corresponding to certain FIG. 4A timing events.

FIG. 5 is an illustration of a wafer surface depression resulting from a laser pulse of the FIG. 1 system.

FIG. 6A illustrates a second example of a laser SCANNER PATH, forming an alphanumeric character (e.g., the number ‘0’) using the FIG. 1 system.

FIG. 6B illustrates laser pulsing positions, along a SCANNER PATH, corresponding to certain FIG. 6A timing events.

FIG. 7 illustrates a third example of a laser SCANNER PATH, forming an alphanumeric character (e.g., the number ‘9’) using the FIG. 1 system.

FIG. 8 illustrates a fourth example of a laser SCANNER PATH, forming an alphanumeric character (e.g., the letter ‘C’) using the FIG. 1 system.

FIG. 9 illustrates a fifth example of a laser SCANNER PATH, forming an alphanumeric character (e.g., the letter ‘W’) using the FIG. 1 system.

FIG. 10 is a flow diagram of an example method for forming and marking a semiconductor structure.

### DETAILED DESCRIPTION

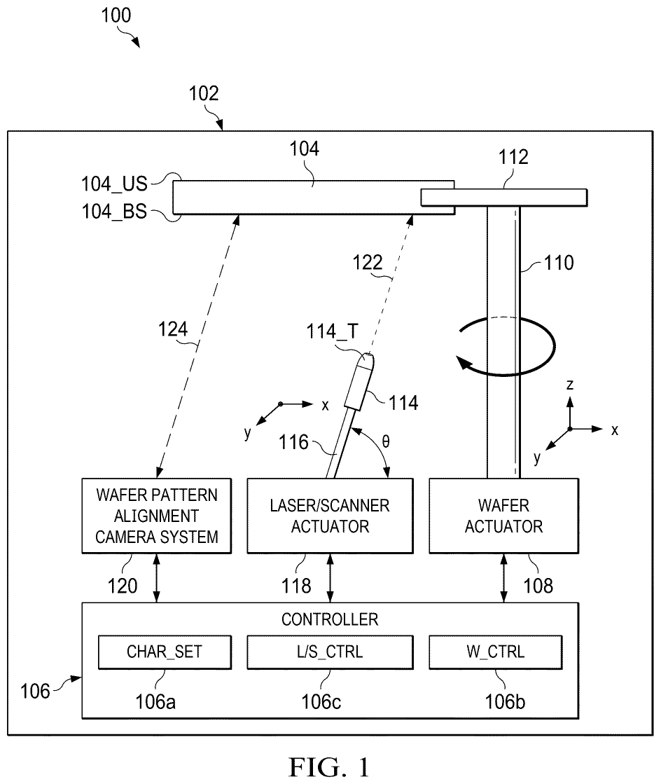

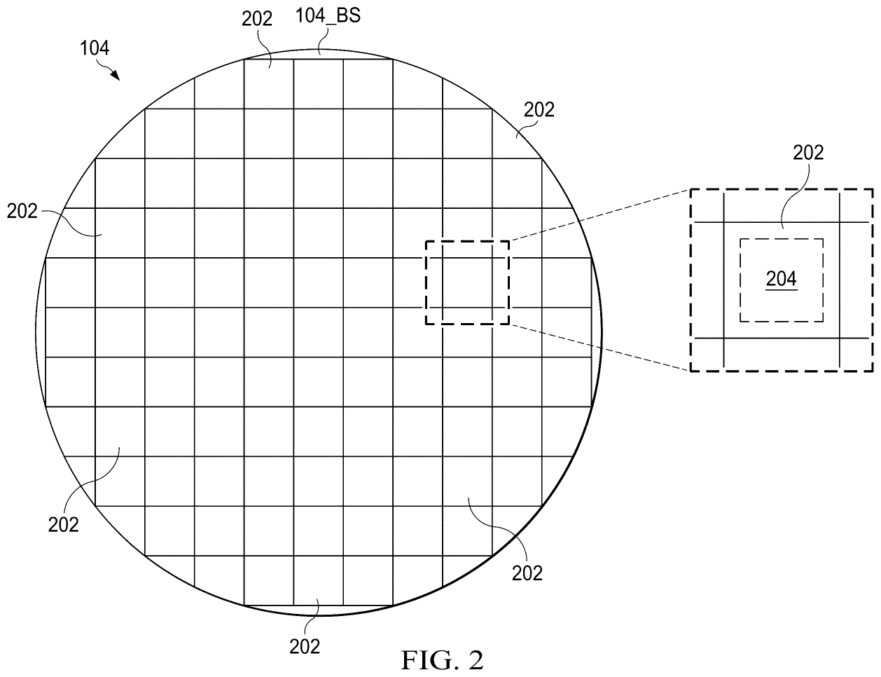

FIG. 1 is a block diagram of a laser marking system 100. The system 100 includes a housing 102 that generally surrounds various apparatus and a semiconductor substrate, such as a semiconductor wafer 104. As detailed in FIG. 2, the semiconductor wafer 104 may include boundaries that define multiple ICs. The apparatus within the housing 102 includes a controller 106, a wafer actuator 108 and an associated first positioning member 110 and second positioning member 112, a laser 114 and an associated laser positioning member 116 and laser/scanner (L/S) actuator 118, and a wafer pattern alignment camera system 120. The various apparatus operate to appropriately and relatively position the wafer 104 and the laser 114, so that the wafer backside 104_BS faces a tip 114_T of the laser 114, while the wafer upper surface 104US, on which typically circuitry is already formed, faces away from the tip 114_T. With this positioning, the controller 106 generates and outputs appropriate control signals, based on a pattern (e.g., character) to be marked on the wafer 104, with the character selected from a character set storage medium (CHAR_SET 106a) that specifies parameters corresponding to the selected character. Further, and according to those parameters, the controller 106 selects one or more parameters from a wafer control signal storage medium (W_CTRL 106b) to generate corresponding signals that actuate the wafer actuator 108 to thereby position the wafer 104. The controller 106 also selects one or more parameters from a laser/scanner control storage medium (L/S_CTRL 106c) to generate corresponding signals that actuate the L/S actuator 118 to position and move the laser 114 and to appropriately select and time its emission (and discontinuation) of light pulses 122. Further, the laser 114 is moved so that its tip 114_T points to paths along, and between, different target positions and creates markings along desired ones of those paths, along the backside 104_BS, where the markings are formed as surface depressions in response to the light pluses 122. Certain marking attributes may be shared, or commonly implemented, in connection with multiple characters in the character set, for example with that set providing alphanumeric characters. These attributes may be commonly applied to those multiple characters, while achieving improved structure and results for some or all characters formed for each wafer IC.

Operation of the controller 106 to position the wafer 104 is now described in more detail. The controller 106 may include a combination of hardware and software/firmware, implemented as a dedicated device or a partially or fully programmable one, such as a microcontroller, microprocessor, or digital signal processor. The controller 106 includes some type of storage media in which instructions and parameters are fixed or loadable, including the CHAR_SET 106a, W_CTRL 106b, and L/S_CTRL 106c media. These instructions/media can be executed/used to perform the operations described in this document. The second positioning member 112 couples to (e.g., retains) the wafer 104 and to the first positioning member 110. The wafer actuator 108, under control of the controller 106, includes electromechanical apparatus operable to move the first positioning member 110 in all three dimensions (shown in FIG. 1 as x/y/z), which may include rotating about the major axis of the first positioning member 110, so as to correspondingly move the second positioning member 112 and the wafer 104. Further, the second positioning member 112 may couple to the wafer 104 from a position other than as shown in FIG. 1, and then may be actuated to move the wafer 104 into the position shown in FIG. 1, so that the wafer 104 is within a vicinity of a desirable distance to be impacted by the light pulses 122 from the laser tip 114_T. Also in this regard, the wafer pattern alignment camera system 120 has a line of focus 124 by which it may capture high-resolution image processing of portions of the wafer backside 104_BS. This image capture may be used to identify specialized pattern locations, such as a predefined alignment mark or feature so as to identify and achieve alignment of the wafer 104. Once the images are captured, either the system 120 or the controller 106 analyzes the images to identify specific features or alignment marks, from which offsets or other alignment corrections are identified by which the controller 106 can further cause the wafer actuator 108 to fine tune the positioning of the wafer 104 (via the first and second positioning members 110 and 112). Sometimes plural, or iterative, corrective adjustments are made to properly position the wafer 104 as described.

As further context for wafer marking, FIG. 2 illustrates a plan view of the backside 104_BS of the wafer 104. The wafer 104 is partitioned into separate IC areas 202, each corresponding to where an independent and separable IC may be formed. Each IC area 202 includes a same overall circuit on a first side (e.g., front side) of the wafer, where the overall circuit may include various different devices and perform one or more (or many) operations. On the opposing backside 104_BS of the wafer 104, each IC area 202 further includes a marking area 204 where marking can be performed on the IC, for example with marking provided by the FIG. 1 system 100. Laser marking can form indications on each IC backside surface, for example by emitting light pulses 122 that cause surface heating or ablation and corresponding surfaced depressions (concave recesses), which when viewed from a distance present as alphanumeric characters, logos, or other indications (e.g., serial, product, or identification numbers).

The system 100 marking on the wafer 104 (e.g., its backside 104_BS) is now described in more detail, with additional demonstrations and explanations in figures referenced below. Once the wafer 104 is properly positioned via the wafer actuator 108, the L/S actuator 118 is controlled such that its electromechanical apparatus moves the laser positioning member 116, and correspondingly the laser 114, in the x-y plane (as may be accomplished also by a tilt angle, θ) to point the laser tip 114_T to a target on the bottom surface 104_BS. Each point along the x-y plane may be identified by, or otherwise correspond to, a coordinate position (x,y). Because control of the system 100 is digital, then the minimum spacing, or resolution, between any two successive values of x, or of y, is limited by the difference that may be specified by the least significant bit (LSB) in the digital number specifying the coordinate. Accordingly, the L/S actuator 118 adjusts and advances the laser tip 114_T target along a line including and between two or more coordinate positions, and as a result a path is effectively traced or scanned along the bottom surface 104_BS. Accordingly, such control is sometimes referred to functionally as a scanner, and each target position to which the tip 114_T points is referred to as a scanner location, as may be represented in the controller 106 (e.g., indicated by a counter or other measure or data value in a storage medium). Further, as the tip 114_T is advanced to point along multiple target positions, the path traversed by those positions may be referred to as a scanner path. Accordingly, such terms are used later in this document. Further, the L/S actuator 118 also enables and disables the laser 114 to emit light pulses 122, and additionally controls timing of the light pulse enabling/disabling, so as to improve the relationship between the timing of the physical movement of the laser 114 and its corresponding scanning path along the wafer 104, and the formation of surface depressions that occur from the timing and enabling/disabling of the laser light pulses 122.

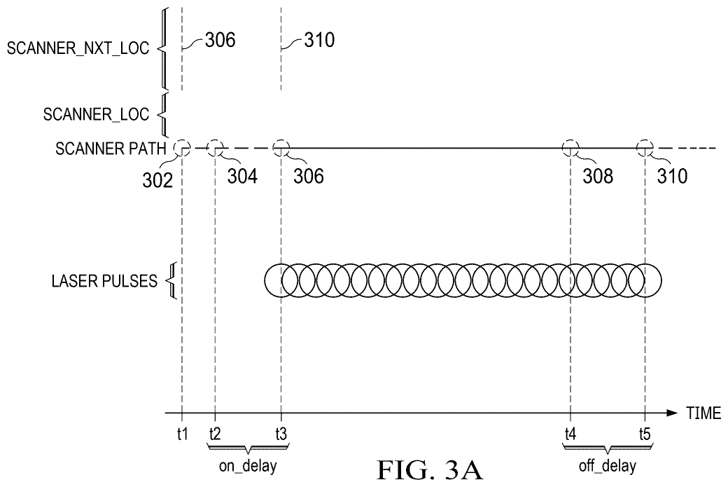

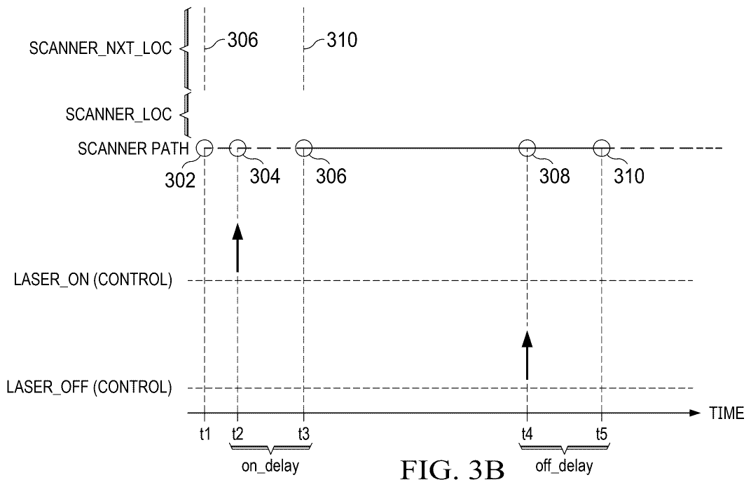

FIGS. 3A and 3B illustrate a laser scanner path (SCANNER PATH) along which the laser tip 114_T points at respective target positions along a surface of the wafer 104, under the control of the controller 106. FIG. 3A further depicts certain timing events and the commencement of LASER PULSES at a time t3, while FIG. 3B shows related events and control signals corresponding to those LASER PULSES. In FIGS. 3A and 3B, the illustrated SCANNER PATH is linear, and it includes five indicated path target positions 302, 304, 306, 308, and 310. Some or all of these target positions can be identified by the system 100 apparatus, for example in the L/S actuator 118, again under control of the controller 106. Thus, each position could be represented by an (x,y) coordinate in the plane in which the tip 114_T may be pointed, but for simplification is shown and referred to as a position with a reference number.

By a time t1, the system 100 is pointing the laser tip 114_T to the target position 302, and the system 100 also stores a next location (SCANNER_NXT_LOC) along the SCANNER PATH, so that the laser tip trace will continue along successive locations. Accordingly, in the FIG. 3A example, the SCANNER PATH at t1 is at the target position 302, and as shown by the SCANNER_NXT_LOC, the line should continue toward target position 306, per a constant trace speed. The constant trace speed may, for example, be one of two different speeds, such as a first and faster speed if the laser 114 is not pulsing as between two positions. The faster speed, without pulsing, correspondingly causes no marking on the semiconductor wafer 104, so such movement may be referred to as “jumping” from one position to the next. For example, the faster jumping trace speed may be 3,000 mm/sec. In contrast, when the laser 114 is pulsing and thereby marking the semiconductor wafer 104, the trace speed is slower. For example, the slower marking speed may be 1,100 mm/sec. FIG. 3A shows the SCANNER PATH as a dashed line immediately following t1, to demonstrate that while the laser tip 114_T is advancing while pointing along a line between positions 302 and 306, the laser light pulses 122 are not yet enabled. Further, therefore, the laser tip 114_T following t1 is moving at the faster jumping speed (e.g., 3,000 mm/sec).

Prior to the laser tip 114_T pointing to the target position 306, and as shown at time t2 when the laser tip 114_T is pointing to a target position 304, the controller 106 and/or L/S actuator 118 asserts a LASER_ON control signal, to enable the pulsing of the laser 114. Such enablement is not instantaneous, however, but occurs after a period shown as the on_delay, which commences with the LASER_ON control signal at t2 and completes at t3. In an example, the duration of the on_delay is set per considerations described later.

At t3, the on_delay completes and the laser 114 begins pulsing, while the laser tip 114_T continues to advance (by the movement from the L/S actuator 118) along the SCANNER PATH, where after t3 the tip advancement speed may be the slower pulsing speed (e.g., 1,100 mm/sec). In FIG. 3A, the pulsing is shown as the LASER PULSES, and in both FIG. 3A and FIG. 3B, pulsing commencing at t3 is shown by the SCANNER PATH changing from a dashed line to a solid line. Also in FIG. 3A with respect to the pulsing, each pulse approximates a circle with a diameter based on the attributes of the laser and centered at the target position at which the laser is pointing. For example, laser radii may be in a range of 35 μm to 45 μm. Accordingly, as the laser tip 114_T advances along the direction of the SCANNER PATH to the SCANNER_NXT_LOC of target position 306, and LASER_ON was asserted at t2, then once the laser is enabled at t3 it is pointing to that location of target position 306, at which point the first laser pulse is emitted. As the laser tip 114_T is advanced to point along the SCANNER PATH while the laser 114 is pulsing, each successive pulse may overlap the immediately preceding pulse, based on the laser frequency (e.g., 66 kHz) as well as the scan rate at which the laser tip 114_T advances along the SCANNER PATH. In other words, the distance between each successive pulse is related to laser velocity and time of pulsing (laser pulse period, that is, the inverse of frequency). In the example illustrated in FIG. 3A, the center pitch, that is the distance between the center of each circular pulse after the first pulse, is equal to the pulse radius, so that each pulse has a perimeter that intersects the center point of the previously-formed circle. In an ideal example in which each laser pulse is circular, then typically an area of a pulse, other than the first pulse in the sequence of pulses, will overlap an area of an immediately preceding pulse, by approximately 30 to 70 percent. In an ideal example in which each laser pulse is circular, then typically a diameter of a pulse, other than the first pulse in the sequence of pulses, will overlap the diameter of an immediately preceding (neighboring) pulse, by approximately 30 to 70 percent. So, in the example illustrated in FIG. 3A, where each pulse (after the first) has a perimeter that intersects the center point of the immediately-preceding pulse, then the diameter overlap between successive center pitch is 50 percent. Also as of t3, SCANNER_NXT_LOC indicates a new next target position 310. Accordingly, the light pulses 122 commence and continue from t3, as the laser 114 also is advanced to point to target positions along the SCANNER PATH, continuing toward the designated SCANNER_NXT_LOC of target position 310.

At time t4, when the laser tip 114_T is pointing to a target position 308, the controller 106 and/or L/S actuator 118 asserts a LASER_OFF control signal, to disable the light pulsing of the laser 114. Such disablement is not instantaneous, however, but occurs after a period shown as the off_delay, which commences while the laser 114 is still enabled and pulsing at t4, and which completes at t5. The duration of the off_delay is set per considerations described later. Accordingly, at time t5, the laser tip 114_T pointing direction along the SCANNER PATH reaches the target position 310, at which position the last laser pulse is applied, after which the laser pulsing is disabled. The L/S actuator 118 may continue to thereafter advance the target direction of the laser tip 114_T along the linear portion of the SCANNER PATH shown, but for such advancement no additional pulses are applied to the wafer surface and correspondingly no marking occurs in that portion of the line.

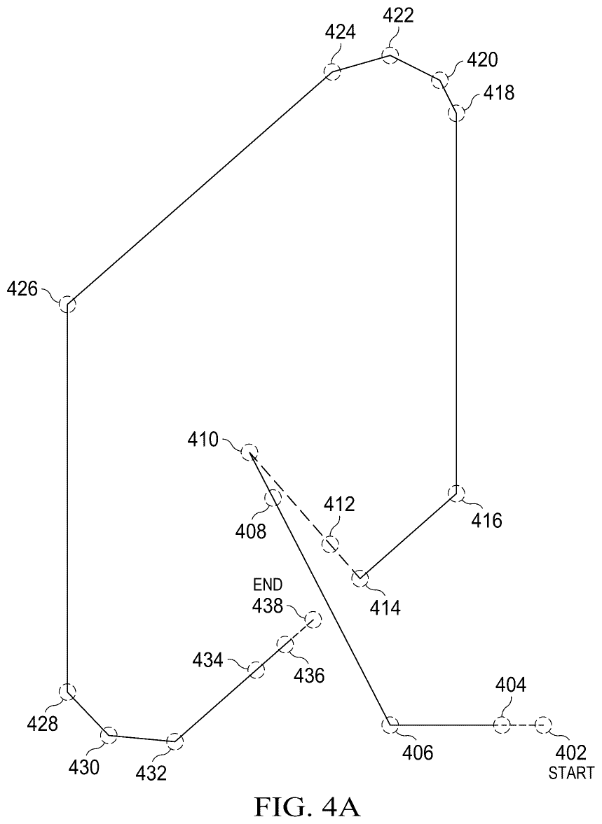

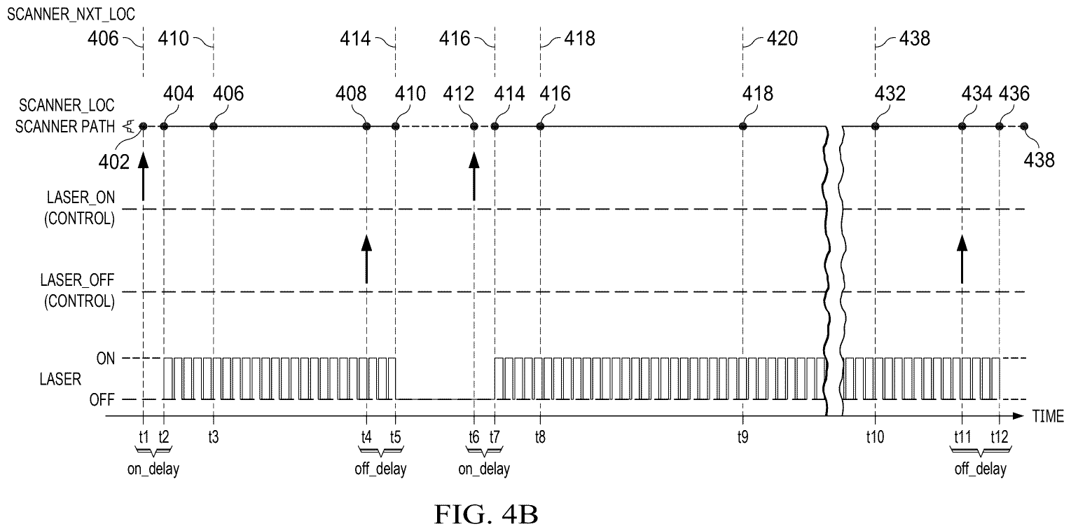

FIG. 4A illustrates a first example of a laser SCANNING PATH, and FIG. 4B illustrates corresponding control signals, forming an alphanumeric character (e.g., the letter Q′) using the FIG. 1 system 100 along that path. The system 100 selects the alphanumeric character ‘Q’ from the CHAR_SET 106a, so as to identify and/or load parameters (e.g., L/S_CTRL 106c) associated with that character. With the wafer 104 appropriately positioned via the wafer actuator 108, the L/S actuator 118 then controls movement of the laser 114 and its tip 114_T, and enablement and disablement of its pulses, to traverse wafer surface paths (e.g., lines) from a START target position 402, through a number of intermediate target positions, to an END target position 438. Additional details with respect to examples along some of these paths are described below.

The FIGS. 4A/4B SCANNER PATH commences at the START target position 402 at t1, at which time the laser pulsing is off and LASER_ON is asserted. Meanwhile, SCANNER_NXT_LOC identifies a next target position 406, which is the end of a linear path between it and the START target position 402. Accordingly, the system 100 points the laser tip 114_T to the START target position 402 and begins to advance the tip along the line toward the target position 406. While the laser tip 114_T advances to point along that path, at time t2, while the tip 114_T points to a target location 404, the on_delay concludes, the laser begins pulsing, and its tip 114_T continues to advance. In response, a first marking line, formed of successive surface depressions corresponding to successive laser pulses, begins to form at the target position 404 and is to continue to and until the target position 406 is reached at t3.

At t3, SCANNER_NXT_LOC indicates a new target position 410. In response, the system 100 directs the tip 114_T along a new path, starting from the target position 406 and heading to the target position 410. Meanwhile, the laser 114 continues to pulse, thereby marking a second line, again formed of successive surface depressions corresponding to successive laser pulses, between target positions 406 and 410. This process continues among additional target positions, so as to collectively mark the alphanumeric character (e.g., ‘Q’) in a piecewise linear manner, forming individual lines, where each line is not co-linear with the line that was formed immediately before it, and with each line specified between two SCANNER_NXT_LOC positions.

At t4, while the L/S actuator 118 continues to advance the tip 114_T along the path between target positions 406 and 410 and when it is pointing to target position 408, LASER_OFF is asserted. Accordingly, the laser 114 continues to pulse until the off_delay is complete at t5, so correspondingly the pulsing, and resultant surface depression markings along the path, continue until t5. At t5, the off_delay is complete as of the time the tip 114_T points to the target position 410, at which time/point the laser pulsing is disabled.

Also by t5, SCANNER_NXT_LOC indicates a new target position 414. In response, the system 100 directs the tip 114_T along a new path, starting, or in effect jumping at a faster tracing speed, from the target position 410 and heading to the target position 414. Meanwhile, however, the laser 114 is disabled from pulsing, due to the t4 assertion of LASER_OFF and the passage of off_delay by t5. Accordingly, from the target position 410 toward the target position 414, FIG. 4A illustrates the SCANNER PATH along which the tip 114_T points in dashed lines, as no pulsing occurs and no surface depressions are formed along that path. However, as the tip 114_T points along that path, at t6, and while the tip 114_T is pointing to target position 412, LASER_ON is asserted. Accordingly, the laser 114 remains disabled but its tip 114_T advances until the on_delay is complete, which occurs at t7, when the tip 114_T is pointing to target position 414.

Also by t7, SCANNER_NXT_LOC indicates a new target position 416. In response, the system 100 directs the tip 114_T along a new (e.g., linear) path, starting from the target position 414 and heading to the target position 416. Further, with the laser 114 having been enabled to pulse following the LASER_ON at t6 and the on_delay to t7, then pulsing commences at the target position 414 and corresponding surface depressions are formed along that path.

At t8, the tip 114_T points to target position 416 and the laser 114 emits a light pulse to cause a corresponding depression at that position. Additionally at that time, SCANNER_NXT_LOC indicates a new target position 418. Accordingly, the L/S actuator 118 adjusts the laser 114 and its tip 114_T to begin point to target positions along a new path, between target positions 416 and 418. Thus, the laser 114 remains on while a corresponding line is marked between target positions 416 and 418, where that line intersects with the already-formed line between target positions 414 and 416.

The above operation and processes repeat to mark numerous additional piecewise linear segments of the alphanumeric character ‘Q’, which is completed with the END target position 438 as part of a final linear path traced by target positions of the tip 114_T. Particularly and as shown in FIG. 4B, at time t10 the target position 432 is reached, and SCANNER_NXT_LOC indicates as a new target position the END target position 438. The L/S actuator 118 adjusts the laser 114 and its tip 114_T to begin point to target positions along the path between target positions 432 and 438, so that a surface-depression line is marked on the wafer surface for the last line in the alphanumeric character. As that path is being formed, at time t11 and as the laser tip 114_T points to the target position 434, LASER_OFF is asserted, and following an off_delay period which completes at t12, the laser 114 is disabled when its tip 114_T points to the target position 436. The L/S actuator 118 may continue to advance the laser tip 114_T toward the END target position 438, but the surface depressions are no longer formed after the target position 436 due to the disablement of light pulsing.

From FIGS. 4A and 4B and the corresponding description, the system 100 is operable to select an alphanumeric character from among a set of characters, and to form the character on a wafer surface by guiding the laser tip 114_T along a series of different paths, for example linear paths. Character formation is performed by selectively enabling and disabling the laser 114 along a portion or all of a first set of paths, while disabling the laser along a portion or all of a second set of paths. When the laser 114 is enabled, pulsing, and advancing to target positions along a path, it forms sequential surface depressions along the corresponding portions of the path. Ultimately, the resultant and cumulative surface depressions depict the selected character. In this manner, the system 100 may include one or two different attributes that further contribute to consistent and robust character formation, as described below.

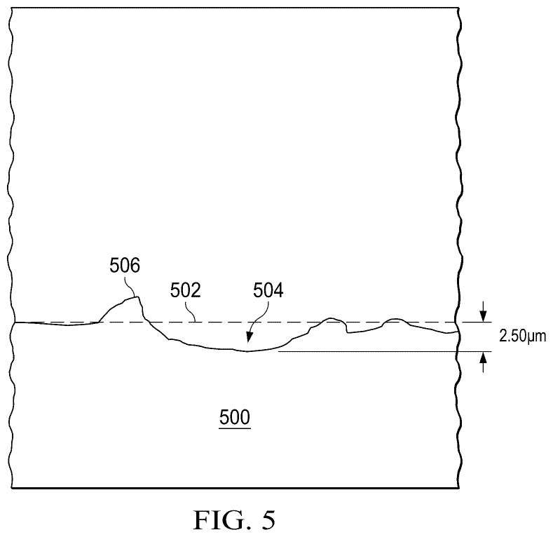

In a first character formation aspect of the system 100, the laser 114 is controlled so that the starting point (e.g., target position) of each path for the character is at a different location from a starting point of an already-formed path in the character, for example by positioning a starting target position for one path at a pulse-diameter-area overlapping or neighboring position, but not the same position, as the area from the pulse created by the ending position for a just-completed path. In this manner, particularly if the laser is pulsing at the time a position changes from one path to a next, there is a reduced chance that the same, or a large majority of a same, target location is pulsed multiple times. Avoiding multiple pulses, or excessive overlap of pulse area, at a same target location correspondingly reduces the chance of excessive surface ablation and depression, and/or surface deformity that could occur, relative to other less-overlapping depressions. For example, FIG. 5 illustrates a cross-sectional view of a wafer 500, with a die surface 502. When a laser pulse impinges the die surface 502, attributes of the pulse (e.g., high temperature) reshape the area of the die surface 502 that receives the pulse. Reshaping can include a concave area forming a depression 504 beneath the die surface 502, as well as portions, such a protuberance 506, that extend away from the die surface 502. As shown, in one example, the system 100 surface depression depth, that is the depth of the depression from an average plane of the die surface 502, is 2.5 μm or less, for example where there is a single pulse or in the area where only two pulses overlap by no more than 70%. In contrast, if an alternative system or process applied multiple (e.g., four) overlapping pulses in a same area, or overlap >70%, the surface depression depth could be excessive, for example up to 5.0 μm or greater. Such excessively deep depressions may produce potential surface vulnerabilities, for example prone to form cracks at the location of the deep depressions. Accordingly, the system 100 can reduce the potential surface depression, for example at intersection points of path segments, by at least 50% so as to reduce excessively overlapping surface depressions. Reducing excessive surface depression depth from overlapping depressions reduces the chance of excessive surface reduction or degradation (and corresponding depression depth), thereby also reducing the chances of surface vulnerability which could include weak points having a greater general depth as opposed to other surface depression areas where the character is formed by regularly-spaced depressions.

In a second character formation aspect of the system 100, the laser 114 pulsing periods are controlled by adjusting one or both of on_delay and off_delay, again to avoid excessive pulsing overlaps. Considerations for each of the on_delay and off_delay are discussed below.

In one aspect it has been observed in connection with system examples that the response and tracing time of the L/S actuator 118 (or other electromechanical apparatus that causes the scanning operation of a marking laser) may be slower than the response time of turning on the laser 114. The system 100 may be controlled (e.g., programmed) to implement precautions in view of this consideration, namely, so as to not start pulsing while the laser tip 114_T is fixed at one target location where multiple pulses could occur, or too soon once the laser tip 114_T begins to trace a path, as such actions may cause excessively overlapping surface depressions. For example, the system 100 achieves this aspect by implementing on_delay to be at least 70 msec. Returning briefly to FIG. 4A and its START target position 402, note then that while the laser tip 114_T points to that position, LASER_ON is asserted and the tip 114_T begins moving to target positions on the path toward target position 406, but an on_delay of 70 msec causes the laser pulsing to begin only once the tip 114_T is pointing to that path at a distance away from the START target position 402, namely, the pulsing starts at target position 404. Accordingly, the chance of excessive areal overlapping pulses prior to that position is eliminated.

Additionally, in another aspect, it has been observed that the response and tracing time of the L/S actuator 118 may be slower than the response time of turning off the laser 114. As an additional (or alternative) precaution, the system 100 may be controlled to cease pulsing before or as the laser trace is stopped, so as to avoid the possibility of the trace stopping at a particular location while the laser pulses multiple times at that location. For example, the system 100 achieves this aspect by implementing the appropriate timing of LASER_OFF with the off_delay to be no more than 95 msec. Retuning again to FIG. 4A, and the END target position 438, note then that while the laser tip 114_T points to the prior position 434, LASER_OFF is asserted so that the off_delay period (of 95 msec) begins to run, so that by the time the tip 114_T reaches position 436, pulsing ceases, which occurs before the laser tip 114_T stops moving when pointing to the END target position 438. In this way, an adequate number of final pulses are provided to create corresponding surface depressions, but this occurs before the laser 114 stops moving, to again avoid excessive areal overlapping pulses occurring at a single position (e.g., at END position 438).

The above attributes, for example as shown in connection with FIGS. 4A and 4B, provide efficient control of the placement and boundaries of the lines that comprise a laser-marked character, and can be applied to multiple characters in a same character set. For example in FIG. 4A, such attributes assist in the control of where the path surface depressions start and end, as well as the gap between target positions 436 and 414. Further, with that gap well-controlled, the line between target positions 406 and 410 can pass through that gap, without unduly overlapping either of the gap-defining target positions 436 and 414. Accordingly, once more benefits may be achieved by reducing or eliminating areas in which multiple pulses could occur in a same area, which could otherwise cause negative effects.

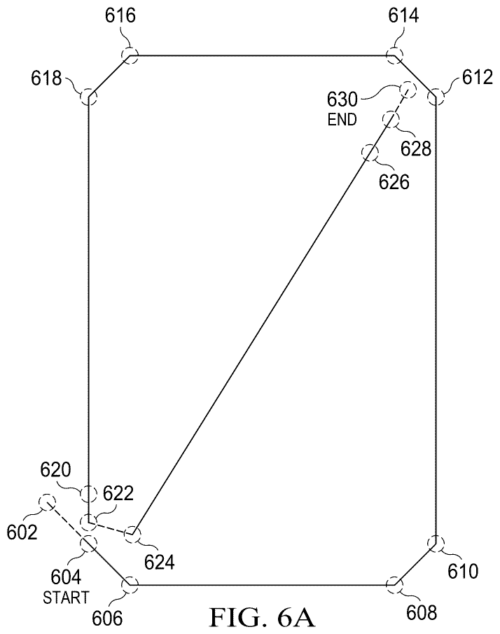

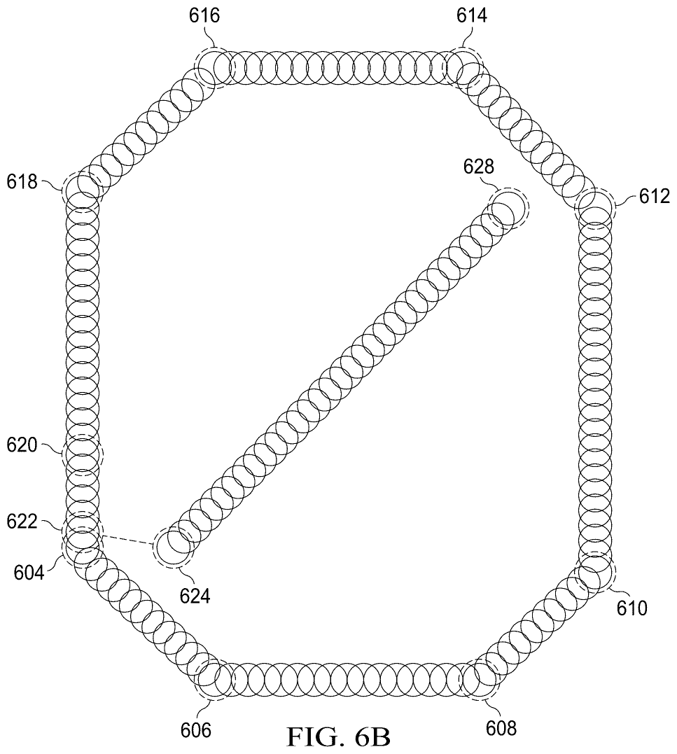

FIG. 6A illustrates a second example of a laser SCANNER PATH, and FIG. 6B illustrates corresponding laser pulsing positions, forming an alphanumeric character (e.g., the digit ‘0’) using the FIG. 1 system 100. The system 100 selects the alphanumeric character ‘0’ from the CHAR_SET 106a, so as to identify and/or load parameters associated with that character. With the wafer 104 appropriately positioned via the wafer actuator 108, the L/S actuator 118 then controls movement of the laser 114 and its tip 114_T, and it enables and disables the laser pulses, to traverse wafer surface paths (e.g., lines) from a START target position 602, through a number of intermediate target positions, to an END target position 630. Generally, the entirety of that path includes and correspondingly marks the outer boundary of the ‘0’ character, as well as a diagonal across it (from an approximate 7 o'clock position to an approximate 1 o'clock position). Additional details with respect to examples along some of these paths are described below.

The outer boundary of the ‘0’ character commences with the system 100 pointing the tip 114_T to the START target position 602, while the laser 114 is not pulsing. In that position, the system 100 asserts LASER_ON and begins to advance the tip 114_T to point along a path (e.g., linear) that ends with target position 606. The on_delay completes and laser pulsing commences when the tip 114_T points to the target position 604, which starts the formation of the surface depressions that will depict the ‘0’ character outer boundary. The tip 114_T advances to point to targets along the linear path toward target position 606, and upon reaching that position a new target position 608 is identified. Accordingly, while the laser 114 continues to pulse, the system 100 adjusts the laser tip 114_T away from the previously-formed linear path between positions 604 and 606, and advances it along a new linear path between positions 606 and 608, with an intersection between those linear paths having a desirably low amount of overlapping pulse area and corresponding surface depressions. The above process repeats, for each of the linear paths shown in FIGS. 6A and 6B forming the outer boundary of the ‘0’ character, with the final of those paths concluding at target position 622. As the system 100 causes the enabled and pulsing laser tip 114_T to traverse that path, at target position 620 the LASER_OFF is asserted, so that the laser 114 stops pulsing once the pulse is applied at the target position 622, at which point a new target position 624 is also available to cause the laser tip 114_T to begin to proceed to point to target positions along a different path, along with pulsing is disabled so surface depressions are not formed, between the target positions 622 and 624.

Either at target position 622 or before reaching target position 624, the system 100 asserts the LASER_ON signal, so that the on_delay completes at the time the tip 114_T is pointing to the target position 624. At that time, the laser 114 begins pulsing, and also by that time the next target position is available, which is the END target position 630 (see FIG. 6A, but not shown in FIG. 6B). Accordingly, the laser tip 114_T continues to traverse and pulse along a new linear path between target position 624 and END target position 630, with that line to provide the diagonal portion of the character ‘0’. The laser tip 114_T continues to traverse that linear path while the laser 114 pulses, corresponding surface depressions are formed, and a LASER_OFF signal is asserted at target position 626. Accordingly, after an off_delay period corresponding to the asserted LASER_OFF, a final pulse is provided at target position 628, thereby completing a formed line of surface depressions that depict the diagonal of the ‘0’ character.

The above attributes, for example as shown in connection with FIGS. 6A and 6B, also provide efficient control of the placement and boundaries of the lines that comprise a laser-marked character, and can be applied to multiple characters in a same character set. So, where FIG. 4A illustrates a character (‘Q’) with a gap in its outer boundary (between target positions 414 and 436), FIGS. 6A and 6B illustrate an outer boundary that can have controlled overlap between pulse-created depressions where the outer boundary nears closing (e.g., positions 604 and 622) and can have one or more paths within the outer boundary, such as the diagonal in the ‘0’ character, that do not pass through an outer boundary gap and that are properly positioned and spaced so as to not unduly overlap with the outer boundary, which otherwise could creative excessive depression overlaps and resultant deep surface removal. Accordingly, again benefits include reducing or eliminating areas in which multiple pulses could occur in a same area.

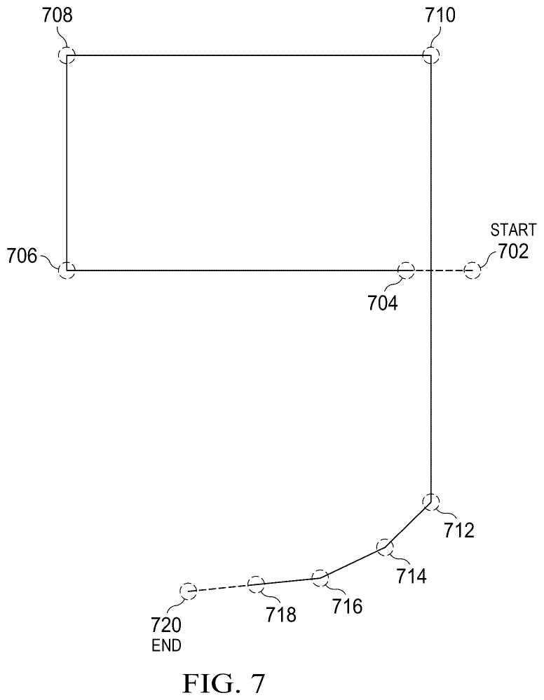

FIG. 7 illustrates a third example of a laser SCANNER PATH forming an alphanumeric character (e.g., the number ‘9’) using the FIG. 1 system 100. The system 100 selects the alphanumeric character ‘9’ from the CHAR_SET 106a, so as to identify and/or load parameters associated with that character. With the wafer 104 appropriately positioned via the wafer actuator 108, the L/S actuator 118 then controls movement of the laser 114 and its tip 114_T, and enablement and disablement of its pulses, to traverse wafer surface paths (e.g., lines) from a START target position 702, through a number of intermediate target positions, to an END target position 720. Generally, the entirety of that path includes moving the laser tip 114_T with the laser off for portions of only the first linear path (from START target position 702 to target position 706) and final linear path (from target position 716 to END target position 720). In the first linear path, the tip 114_T initially points to the START target position 702 and starts moving to the target position 706, and LASER_ON is asserted so that pulsing starts at the target position 704 and continues for the rest of the linear path, and several linear paths thereafter. In the final linear path, the tip 114_T initially points to the target position 716 and continues moving to the END target position 720, but LASER_OFF is asserted before the target position 718 is pointed to by tip 114_T, so that pulsing stops (after off_delay completes) at the target position 718, while the tip 114_T may continue to traverse the rest of the linear path ending at the END target position 720. Additional details with respect to the example should be understood from the preceding examples.

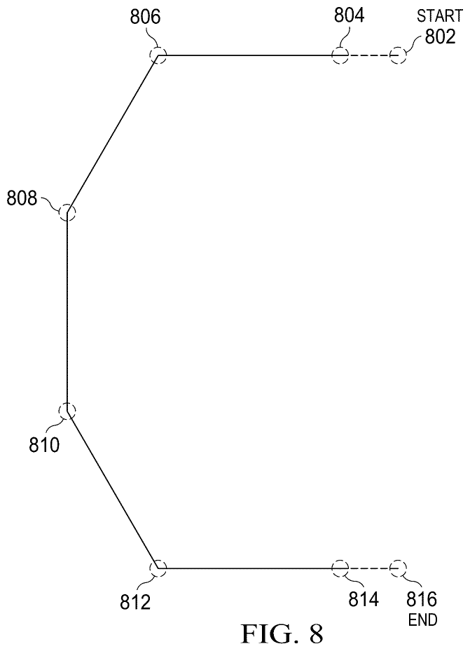

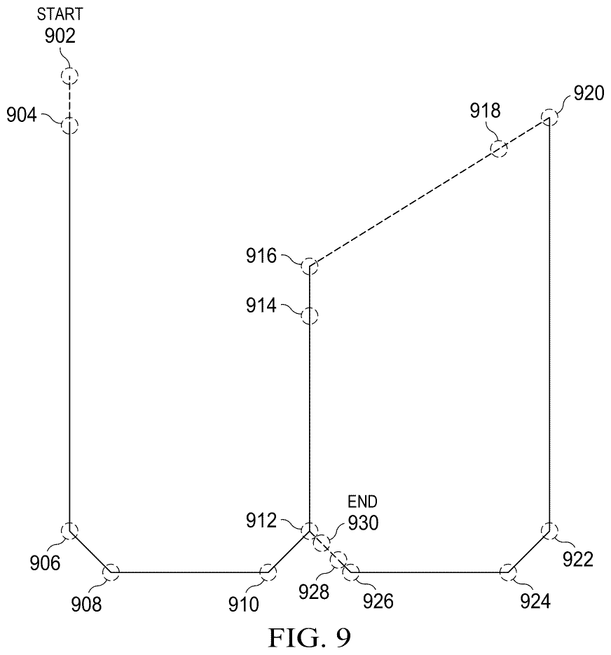

Note that the Figures illustrate the letters and numbers Q, ‘0’ and ‘9’ by example, and other alphanumeric characters also may be formed with a number of segments. As additional examples, FIGS. 8 and 9 illustrate sequences, consistent with the above descriptions, for the letters ‘C’ and ‘W’, respectively.

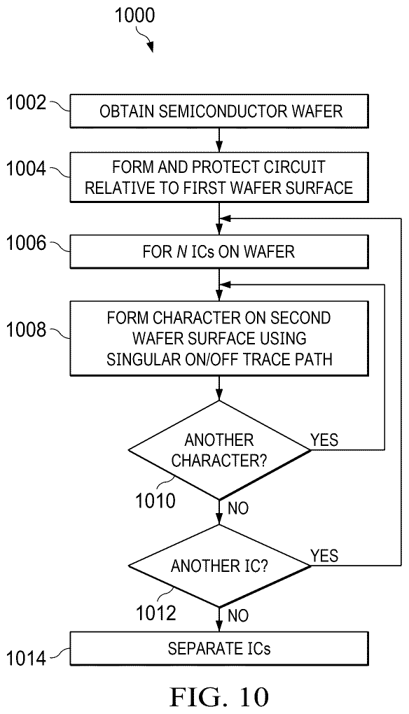

FIG. 10 is a flow diagram of an example method 1000 that summarizes various of the above-described steps for FIGS. 1 through 9. The method 1000 begins in a step 1002, in which the FIG. 1 semiconductor substrate 104 is obtained. The semiconductor substrate 104, at this stage, may be a bare wafer or may have one or more semiconductor features already formed on a first surface, such as the upper surface, of the substrate. The semiconductor substrate 104 also includes one or more areas, or one or more electrical structures adjacent to such an area, in which it is desirable to form semiconductor or silicon including devices. Next, step 1004 forms electrical structures in each area, and protective layering, such as isolation, repassivation, and/or encapsulation of each area. Next, step 1006 starts a loop, for a total of an integer NICs on the semiconductor substrate 104, with the loop including laser steps 1008 and 1010. In step 1008, a character is selected from a character set and formed on a second surface of the substrate 104, such as on its backside. The character is formed with a laser marking system using a singular continuous trace path, comprising a number of segments. For each segment, the laser may be on for the entirety of the segment or a portion of it, and either a predetermined on_delay or off_delay may be used for those segments for which the laser is not on during the entirety of the trace of the segment. Next in step 1010, a condition is checked as to whether an additional character is to be formed for the current IC in the set of NICs, and if so, the method returns to step 1008 to form that next character. If the character sequence is complete for the current IC as determined by step 1010, then a next step 1012 determines if another IC in the NICs remained that is not yet marked. If so, the method returns to the step 1006 to process the next IC, and if not, the method continues to a step 1014. In the step 1014, the encapsulated and marked ICs are separated from one another.

From the above, one skilled in the art will appreciate that examples are provided for semiconductor IC fabrication, for example with respect to laser marking of an IC. Various examples have been described which may achieve one or more benefits. Some examples trace alphanumeric characters, with representative examples provided of numbers and/or letters having varying attributes and in which some of the benefits may be realized. These benefits also may be achieved in structures of varying complexity, or for multiple devices on the same substrate (and IC), thereby realizing scaled improvement across the device. Still additional modifications are possible in the described examples, and other examples are possible, within the scope of the following claims.

What is claimed is:

1. A method of forming an integrated circuit, comprising:
forming circuitry relative to a first side of a semiconductor layer; and
forming an alphanumeric character having a plurality of linear segments on a surface comprising, or fixed relative to, a second side of the semiconductor layer opposite the first side, wherein each linear segment in the plurality of linear segments has a start point and an end point, the forming an alphanumeric character comprising controlling a tip of a laser to point to a series of laser pulse target positions along a path of the surface while enabling the laser to selectively apply light pulses to form a surface depression corresponding to each light pulse and along at least a portion of the path, the path traversing from a first linear segment of the plurality of linear segments to a final linear segment of the plurality of linear segments, without any segment of the plurality of segments having a start point overlapping a start point of a previously-formed segment.

2. The method of claim 1, wherein the forming an alphanumeric character occurs without any segment of the plurality of segments having an end point overlapping a start point of a previously-formed segment.

3. The method of claim 1, wherein the forming an alphanumeric character further comprises:
communicating an on-signal to the laser, in response to which and after an on-delay, the laser emits light pulses at a plurality of the laser pulse target positions; and
communicating an off-signal to the laser, in response to which and after an off-delay, the laser stops emitting light, to conclude formation of a linear segment.

4. The method of claim 3:
wherein the on-delay is at least 70 msec; and
wherein the off-delay is at least 95 msec.

5. The method of claim 1, wherein the laser tip translates relative to the surface at a same rate while the laser is enabled.

6. The method of claim 5, wherein the laser tip translates relative to the surface at a different rate while the laser is disabled.

7. A method of forming an integrated circuit, comprising:
forming circuitry over or extending into to a first side of a semiconductor layer;
selecting an alphanumeric character from a parameter set characterizing a plurality of alphanumeric characters, each alphanumeric character in the parameter set having a start point, an end point, and a plurality of segments between the start point and the end point; and
forming the selected alphanumeric character on a surface comprising, or fixed relative to, a second side of the semiconductor layer opposite the first side, comprising the steps of:
controlling a tip of a laser to advance along a series of laser target positions along a path from the start point to the end point;
enabling laser pulses from the laser after the tip of the laser begins to advance; and
disabling laser pulses from the laser before the tip of the laser reaches a position to point to the end point; and
wherein the controlling step controls the tip of the laser to prevent the tip from pointing to a position along the path in which a prior pulse has occurred in forming the selected alphanumeric character.

8. The method of claim 7 wherein the enabling step occurs at least 70 msec after the tip of the laser begins to advance.

9. The method of claim 7 wherein the disabling step occurs at least 95 msec laser before the tip of the laser reaches a position to point to the end point.

10. The method of claim 7:
wherein the enabling step occurs at least 70 msec after the tip of the laser begins to advance; and
wherein the disabling step occurs at least 95 msec laser before the tip of the laser reaches a position to point to the end point.

11. The method of claim 7, wherein the plurality of segments each comprises a plurality of line segments, and wherein the forming step further comprises disabling the laser from pulsing while controlling the tip to advance along an entirety of a line segment in the plurality of line segments.

12. The method of claim 7, wherein the enabling step comprises enabling a series of laser pulses to form corresponding surface depressions on the surface, wherein no two pulses in the formation of the alphanumeric character overlap the surface so as to form corresponding surface depressions that overlap in area by 25 percent or more.

13. An integrated circuit (IC), comprising:
circuitry positioned relative to a first side of a semiconductor layer; and
a plurality of alphanumeric characters formed relative to a second side of the semiconductor layer, wherein each character in the plurality of alphanumeric characters comprises a plurality of surface depressions along a path defining the character and wherein each surface depression is 2.5 μm or less.

14. The IC of claim 13 wherein each character in the plurality of alphanumeric characters comprises a plurality of lines, each line comprising a plurality of the surface depressions.

15. The IC of claim 13 wherein each of the plurality of the surface depressions comprises a circular outer boundary.

16. The IC of claim 15 wherein each of the plurality of surface depressions overlaps at least one neighboring surface depression in an area of overlapping range from 30 to 70 percent.

17. The IC of claim 15 wherein each of the plurality of surface depressions overlaps at least one neighboring surface depression in an overlapping area of no more than 70 percent.

18. The IC of claim 13, wherein each character in the plurality of alphanumeric characters comprises a plurality of piecewise linear markings, each piecewise linear marking intersecting only at one or both ends with a respective different piecewise linear marking in the plurality of piecewise linear markings.

19. The IC of claim 13, wherein each character in the plurality of alphanumeric characters comprises a plurality of piecewise linear markings, wherein at least one piecewise linear marking passes through a gap between endpoints of two other piecewise linear markings in the plurality of piecewise linear markings.

20. The IC of claim 13, wherein none of the surface depressions overlaps another surface depression by more than 70%.
